(19) United States
(12) Patent Application Publication
(10) Pub. No.: US 2026/0223478 A1
(43) Pub. Date: Jul. 30, 2026

(54) METHODS FOR CONTROLLING BLISTERING IN PASSIVATING CONTACTS OF BACKSIDE CONTACT SOLAR CELLS

(71) Applicant: Maxeon Solar Pte. Ltd., Singapore (SG)

(72) Inventors: Roderick Marstell, San Jose, CA (US); David D. Smith, Campbell, CA (US)

(73) Assignee: Maxeon Solar Pte. Ltd., Singapore (SG)

(21) Appl. No.: 19/037,264

(22) Filed: Jan. 26, 2025

(51) Int. Cl. H10F 77/20; H10F 10/14; H10F 71/00

(52) U.S. Cl. CPC H10F 77/211; H10F 10/14; H10F 71/1221

(57) ABSTRACT

A method of forming a solar cell. The method includes forming a multilayered stack of materials including a substrate, forming a plurality of openings in the top layer of the multilayered stack of materials, forming a plurality of dielectric regions, that are aligned to the plurality of openings, on a polysilicon layer of the multilayered stack of materials, forming a plurality of trenches around the plurality of dielectric regions to form a plurality of first polysilicon regions and one or more second polysilicon regions wherein the one or more second polysilicon regions include a carbon containing amorphous silicon layer on their top surface having a first doping type, and forming a dielectric layer having a second doping type above the plurality of first polysilicon regions and the carbon containing amorphous silicon layer. The method includes in a doping operation, using the carbon containing amorphous silicon layer to cause the one or more second polysilicon regions to have the first doping type, and in the doping operation, using the dielectric layer having the second doping type to cause the plurality of first polysilicon regions to have the second doping type.

### TECHNICAL FIELD

Embodiments of the disclosure pertain to solar cells and, in particular, controlling blistering in passivating contacts of solar cells.

### BACKGROUND

Solar cells are devices for converting solar radiation to electrical energy. They may be fabricated on a semiconductor wafer using semiconductor processing technology. A solar cell includes p-type and n-type doped regions. Solar radiation impinging on the solar cell creates electrons and holes that migrate to the doped regions and create voltage differentials between them that generate electrical current. In a backside contact solar cell, both doped regions and metal contacts are located on the backside of the solar cell. The metal contacts allow external electric circuits to be coupled to and powered by the solar cell. Efficiency is an important characteristic of solar cells that is related to their capacity to generate power. However, there are significant challenges related to the design and fabrication of solar cells with improved efficiency.

### BRIEF DESCRIPTION OF THE DRAWINGS

FIG. 1A illustrates an exemplary operating environment of photovoltaic modules that include solar cells formed by methods for controlling blistering in passivating contacts of backside contact solar cells according to one embodiment.

FIG. 1B shows a cross-section of a portion of a solar cell formed by methods for controlling blistering in passivating contacts of backside contact solar cells according to one embodiment.

FIG. 1C illustrates the positioning of a plurality of trenches around a plurality of polysilicon structures in the solar cell of FIG. 1B according to one embodiment.

FIGS. 2A-2O are illustrations of cross-sections of a multilayered semiconductor structure during fabrication of a solar cell according to one embodiment.

### DESCRIPTION OF THE EMBODIMENTS

Methods for controlling blistering in passivating contacts of backside contact solar cells are described. It should be appreciated that although embodiments are described herein with reference to example methods for controlling blistering in passivating contacts of backside contact solar cells, the disclosure is more generally applicable to methods for controlling blistering in passivating contacts of backside contact solar cells as well as other type methods for controlling blistering in passivating contacts of backside contact solar cells. In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “diffusion” is intended to refer to the precisely controlled introduction of dopants into a material, by means of a solid, liquid or gaseous source, to give the material desired properties.

As used herein the term “diffused region” is intended to refer to a region of a volume of material, where dopants have been introduced by diffusion, that has a larger concentration of dopants than does the volume of material in general.

As used herein the term “doped region” is intended to refer to a region of a volume of material, where dopants have been introduced, that has a larger concentration of dopants than does the volume of material in general.

As used herein the term “doping” is intended to refer to the introduction of impurity elements into material to give the material desired properties.

In one embodiment, as used herein “doping” can be performed by methods that can include but are not limited to diffusion and ion implantation.

In one embodiment, as used herein the term “dotted” is intended to refer to a structural organization of polysilicon in a solar cell that is characterized by the presence of an ordered plurality of non-contiguous and electrically separated polysilicon islands that are surrounded by trenches.

In one embodiment, as used herein the term “polysilicon” is intended to refer to polysilicon, or polysilicon that contains impurities that can include but are not limited to oxygen and carbon.

In one embodiment, as used herein the term “backside” is intended to refer to a backside of a solar cell that is opposite to the front side of the solar cell, wherein the front side of the solar cell faces the sun during normal operation. In one embodiment, as used herein the term “backside contact solar cell” is intended to refer to a solar cell where all electrical connections to its collection regions are formed on its backside. In one embodiment, in a backside contact solar cell, both doped regions and interdigitated metal contact fingers coupled to them, are located on the backside of the solar cell. In one embodiment, the contact fingers allow an external electrical circuit to be coupled to and powered by the solar cell.

In one embodiment, the term “non-contiguous” polysilicon is intended to refer to non-continuous and separated portions of polysilicon. In particular, to a plurality of non-continuous and separated (by surrounding trenches) polysilicon islands having a bounded periphery that can include various shapes.

Solar cells convert solar radiation to electrical energy. A solar cell typically includes p-type and n-type doped regions. Solar radiation impinging the surface of the solar cell creates electrons and holes that migrate to the doped regions and cause voltage differentials to develop between the doped regions. In a backside contact solar cell, the doped regions and metal contacts that are coupled to them are located on the backside of the solar cell. The metal contacts allow an external electrical circuit to be coupled to and powered by the solar cell.

Solar cell efficiency is an important operational characteristic of solar cells as solar cell efficiency is directly related to its capacity to generate power. “Blistering” refers to the formation of bubbles or raised areas on surfaces of a solar cell. It typically occurs within the layers of the solar cell and can significantly reduce solar cell efficiency by disrupting electrical pathways. Moreover, blistering can impact the overall quality of the solar cell. It is considered a major issue that affects the performance and lifespan of a solar cell. Amorphous silicon is a semiconductor material that is prone to blistering that can be used in the fabrication of solar cells.

A method for controlling blistering in passivating contacts of backside contact solar cells is disclosed herein that addresses these challenges. The method includes forming a multilayered stack of materials including a substrate, forming a plurality of openings in the top layer of the multilayered stack of materials, forming a plurality of dielectric regions, that are aligned to the plurality of openings, on a polysilicon layer of the multilayered stack of materials, forming a plurality of trenches around the plurality of dielectric regions to form a plurality of first polysilicon regions and one or more second polysilicon regions wherein the one or more second polysilicon regions include a carbon containing amorphous silicon layer on their top surface having a first doping type, and forming a dielectric layer having a second doping type above the plurality of first polysilicon regions and the carbon containing amorphous silicon layer. The method includes in a doping operation, using the carbon containing amorphous silicon layer to cause the one or more second polysilicon regions to have the first doping type, and in the doping operation, using the dielectric layer having the second doping type to cause the plurality of first polysilicon regions to have the second doping type.

The method involves the fabrication of solar cells using a process that reduces or eliminates blistering of the amorphous silicon material that is used in the passivating contacts located in the field region of the solar cells. In particular, the solar cells fabricated utilizing this process include a thin layer of carbon-containing polysilicon within the polysilicon contact that helps to prevent blistering. As such, the solar cell is designed to avoid the significant reduction in solar cell efficiency that can be caused by blistering. Furthermore, the reduction of blistering has a favorable effect on the performance and lifespan of the solar cell.

### Solar Cell

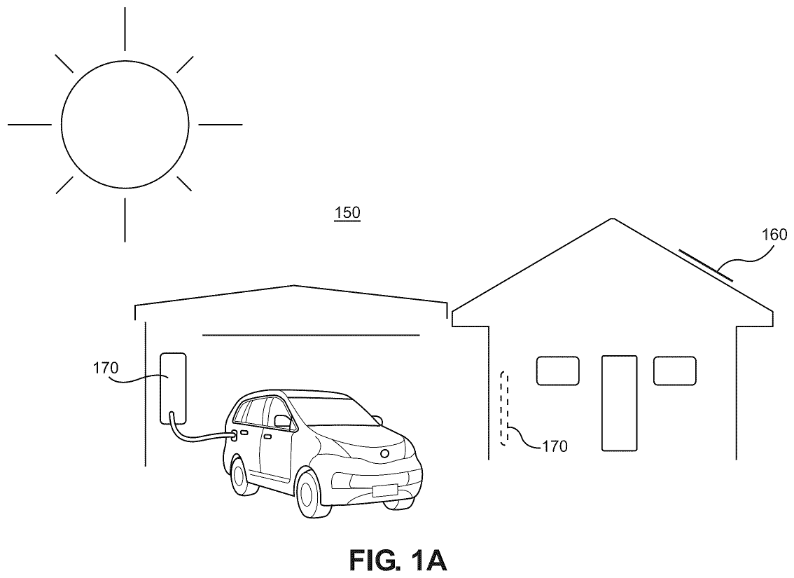

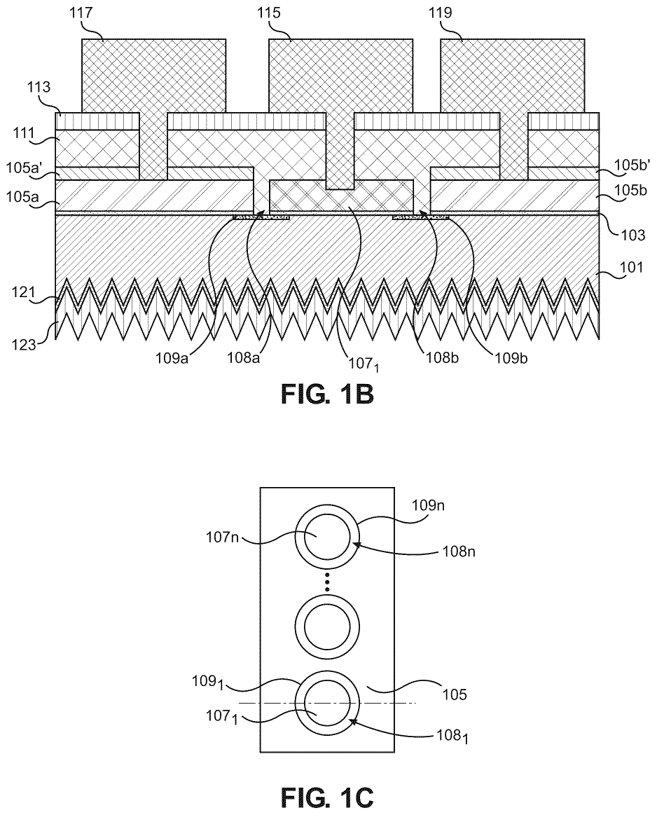

FIG. 1A illustrates an exemplary operating environment 150 of photovoltaic modules having solar cells that are fabricated using methods for controlling blistering in passivating contacts of backside contact solar cells according to one embodiment. FIG. 1A shows a house that has photovoltaic modules 160 that include solar cells (hereinafter “the solar cells” or “a solar cell” or “the solar cell”) that are installed on its roof. In one embodiment, the photovoltaic modules 160 utilize the electrical energy generated by the solar cells to supply the house with electricity (e.g., to power appliances 170). It should be noted that the depicted residential operating environment is only exemplary and that embodiments are equally useful in many other types of operating environments such as commercial environments.

FIG. 1B shows a cross-section of a portion of a solar cell 100 (such as are a part of the photovoltaic modules 160) according to one embodiment. In one embodiment, the solar cell 100 includes wafer 101, tunnel oxide 103, n-doped polysilicon region 105a, n-doped amorphous silicon (a-Si) region 105a′, n-doped polysilicon region 105b, n-doped amorphous silicon (a-Si) region 105b′, p-doped polysilicon layer 1071, trench 108a, trench 108b, doped region 109a, doped region 109b, dielectric layer 111, dielectric layer 113, conductor layer 115, conductor layer 117, conductor layer 119, dielectric layer 121, and dielectric layer 123.

Referring to FIG. 1B, the wafer 101 forms the substrate upon which the semiconductor, dielectric and conductor layers of the solar cell 100 are formed. In one embodiment, the tunnel oxide 103 is formed on the surface of the wafer 101 and includes spaces through which the doped regions 109a and 109b are formed, and in which the dielectric layer 111 is formed. In one embodiment, the p-doped polysilicon layer 1071 is formed on a portion of the tunnel oxide 103 between laterally situated n-doped polysilicon region 105a and n-doped polysilicon region 105b. In one embodiment, the p-doped polysilicon layer 107₁ includes sides that are covered by the dielectric layer 111 and a top surface that is partially covered by the dielectric layer 111. In addition, in one embodiment, the p-doped polysilicon layer 1071 is contacted on its top surface through a space in the dielectric layer 111 by conductor layer 115. In one embodiment, the n-doped polysilicon regions 105a and 105b are formed on the surface of the tunnel oxide 103 and are separated from the p-doped polysilicon layer 107₁ by portions of the dielectric layer 111 that extend into the space that surrounds the p-doped polysilicon layer 107₁. In one embodiment, the doped region 109a is formed in the wafer 101 below a portion of the dielectric layer 111 that extends into a first space in the tunnel oxide 103. In addition, in one embodiment, the doped region 109a laterally extends underneath a portion of the tunnel oxide 103 that is formed underneath the p-doped polysilicon layer 107₁ and a portion of the tunnel oxide 103 that is formed underneath the n-doped polysilicon region 105a. In one embodiment, the doped region 109b is formed in the wafer 101 below a portion of the dielectric layer 111 that extends into a second space in the tunnel oxide 103. In addition, in one embodiment, the doped region 109b laterally extends underneath a portion of the tunnel oxide 103 that is formed underneath the p-doped polysilicon layer 107₁ and a portion of the tunnel oxide 103 that is formed underneath the n-doped polysilicon region 105b. In one embodiment, the dielectric layer 111 extends along the top and inner side surface of the n-doped polysilicon region 105a, on the surface of the wafer 101 between the n-doped polysilicon region 105a and the p-doped polysilicon layer 107₁, along the top and side surfaces of the p-doped polysilicon layer 107₁, on the surface of the wafer 101 between the p-doped polysilicon layer 107₁ and the n-doped polysilicon region 105b, and along the top and inner side surface of the n-doped polysilicon region 105b. In one embodiment, the dielectric layer 113 covers and extends along the entire the top surface of the dielectric layer 111. In one embodiment, n-doped amorphous silicon (a-Si) region 105a′, the dielectric layer 111 and the dielectric layer 113 include an opening above the n-doped polysilicon region 105a that enables the n-doped polysilicon region 105a to be contacted by the conductor layer 117. In one embodiment, the dielectric layer 111 and the dielectric layer 113 include an opening above the p-doped polysilicon layer 107₁ that enables the p-doped polysilicon layer 107₁ to be contacted by the conductor layer 115. In one embodiment, n-doped amorphous silicon (a-Si) region 105b′, the dielectric layer 111 and the dielectric layer 113 include an opening above the n-doped polysilicon region 105b that enables the n-doped polysilicon region 105b to be contacted by the conductor layer 119. In one embodiment, the dielectric layer 121 is formed on the textured frontside surface of the solar cell 100. In one embodiment, the dielectric layer 123 is formed on the dielectric layer 121 on the frontside of the solar cell 100.

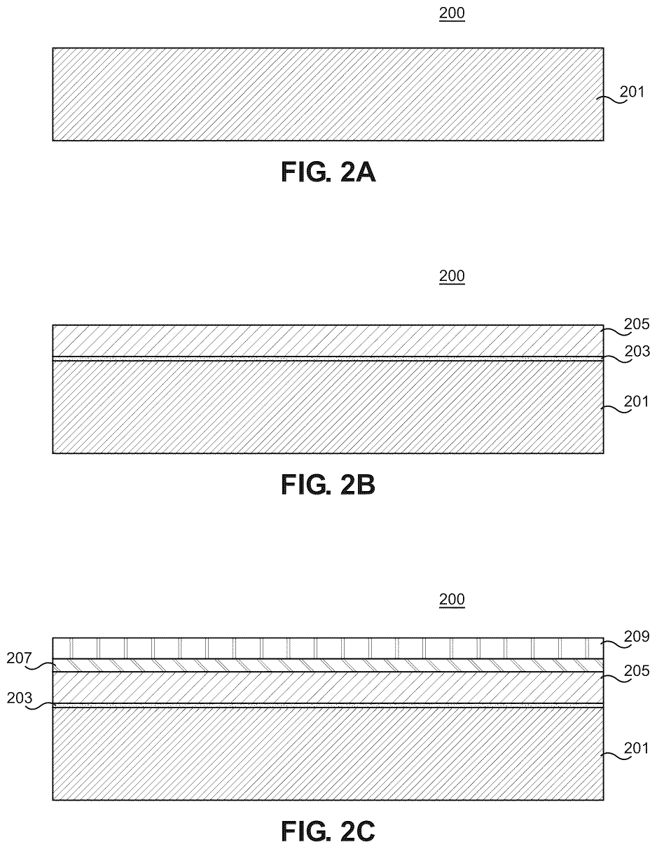

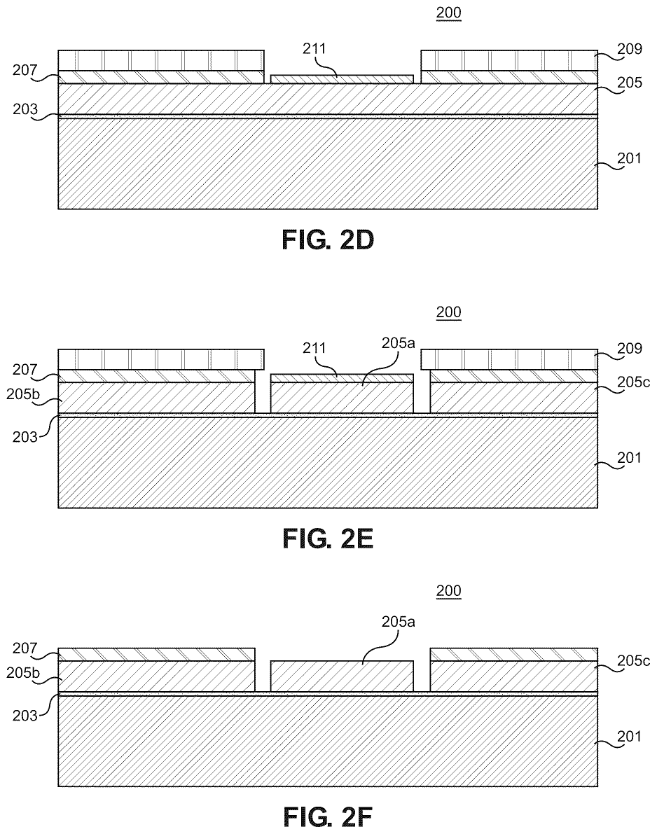

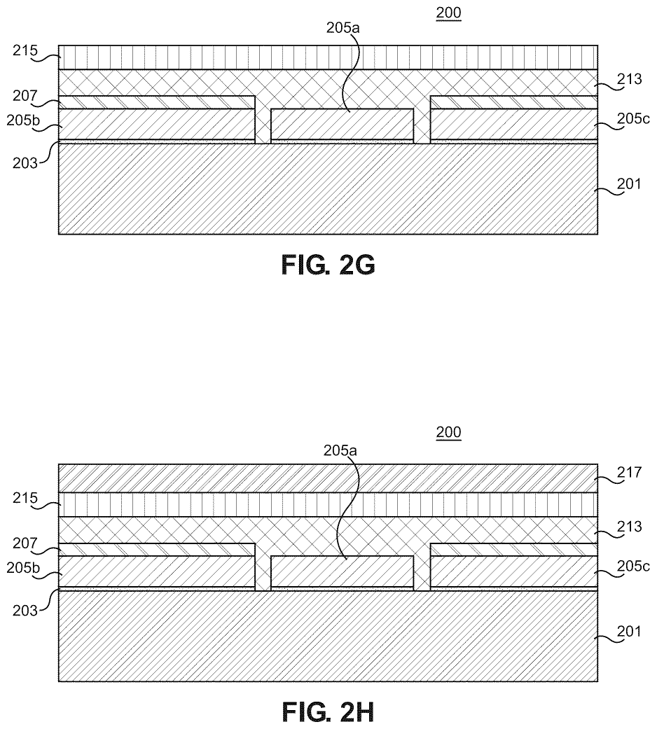

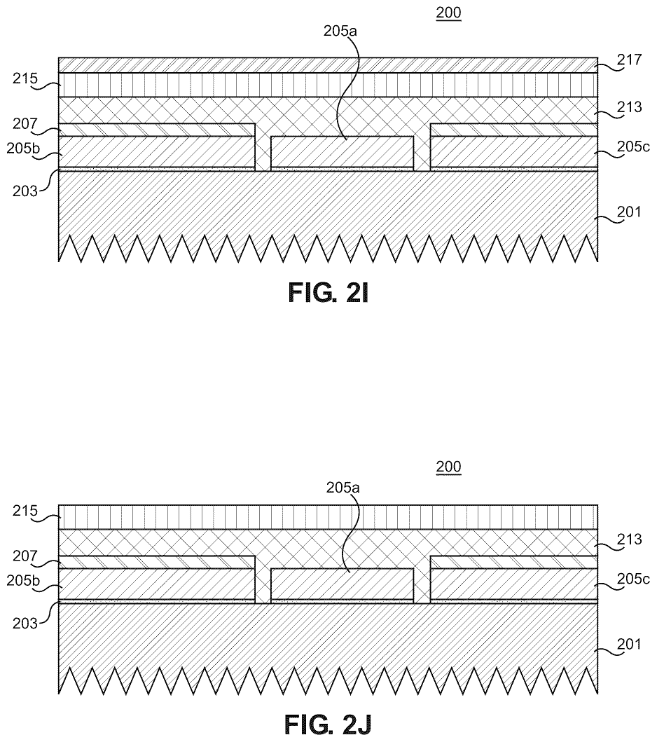

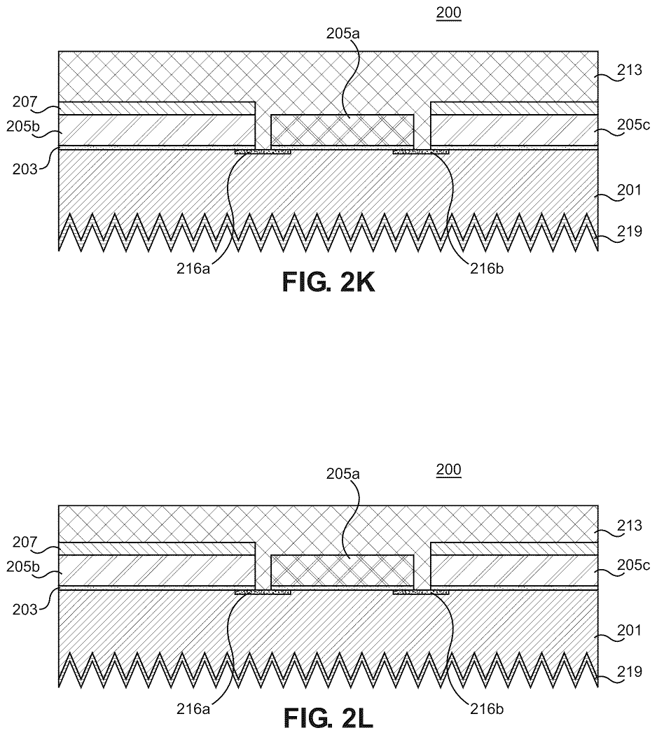

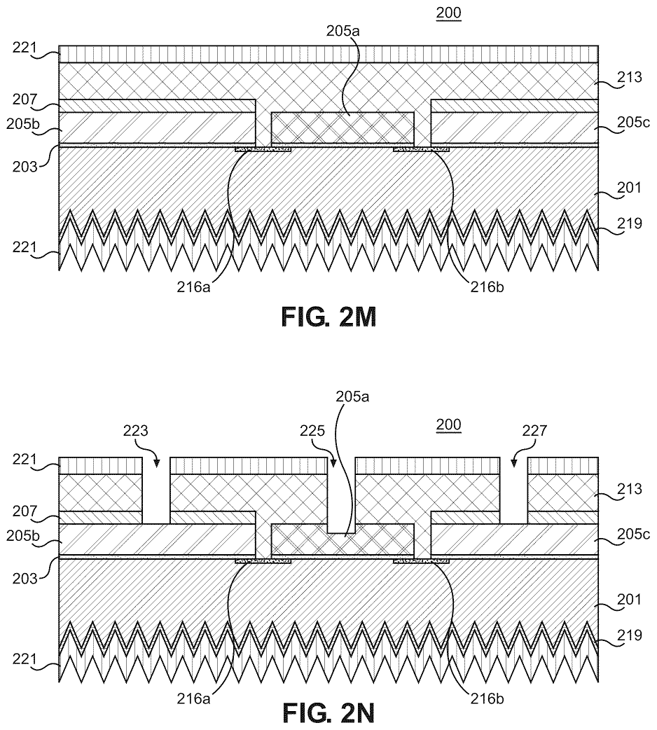

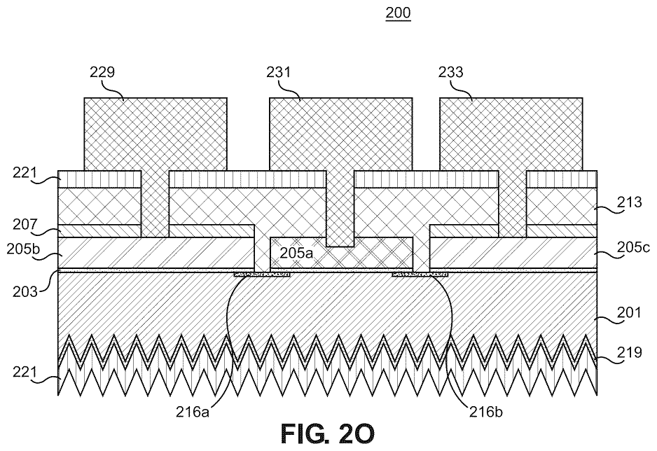

Referring to FIG. 1C, in one embodiment, the trenches 108a and 108b, shown in FIG. 1B, are opposite side cross-sectional parts of a trench 108₁ that is formed around the p-doped polysilicon layer 107₁ (a cross-sectional representation of a first polysilicon island of a plurality of polysilicon islands). Moreover, in one embodiment, the trench 108₁ is one of a plurality of trenches 108₁-108ₙ formed around the plurality of polysilicon islands 107₁-107n (that constitute non-contiguous or “dotted” passivating contact regions) in solar cell 100 (see FIG. 1C). In one embodiment, the trenches can have shapes that can include but are not limited to circular, rectangular, elongated, elliptical, polygonal and irregular. In one embodiment, the polysilicon islands 107₁-107ₙ have a thickness of 110 nm or less. In other embodiments, the polysilicon islands 107₁-107ₙ have other thicknesses. For example, thicknesses greater than 110 nm (e.g., for uses that involve solar cell efficiencies associated with polysilicon island thicknesses greater than 110 nm). In one embodiment, the trenches 108₁-108ₙ are formed using a self-aligned process that is described herein with reference to FIGS. 2A-2O.

In one embodiment, the polysilicon islands 107₁-107ₙ are a plurality of non-contiguous doped polysilicon regions of p-type conductivity that are formed in laser-ablated regions of the semiconductor structure (see FIGS. 2A-2O).

Referring again to FIG. 1B, in one embodiment, the wafer 101 can be formed from silicon. In other embodiments, the wafer 101 can be formed from other materials. In one embodiment, the tunnel oxide 103 can be formed from silicon oxide. In other embodiments, the tunnel oxide 103 can be formed from other materials. In one embodiment, the n-doped polysilicon regions 105a and 105b can be doped with phosphorous. In other embodiments, the n-doped polysilicon regions 105a and 105b can be doped with other impurities. In one embodiment, the n-doped a-Si regions 105a′ and 105b′ can be doped with phosphorous. In other embodiments, the n-doped a-Si regions 105a′ and 105b′ can be doped with other impurities. In one embodiment, the p-doped polysilicon layer 1071 can be doped with boron. In other embodiments, the p-doped polysilicon layer 1071 can be doped with other impurities. In one embodiment, the doped regions 109a and 109b can be doped with boron. In other embodiments, the doped regions 109a and 109b can be doped with other materials. In one embodiment, the dielectric layer 111 can include borosilicate glass. In other embodiments, dielectric layer 111 can include other materials. In one embodiment, the dielectric layer 113 can include silicon nitride. In other embodiments, the dielectric layer 113 can include other materials. In one embodiment, the conductor layer 115 can include aluminum, nickel, chromium, gold, germanium, copper, silver, titanium, tungsten, tin, platinum, and tantalum. In other embodiments, the conductor layer 115 can include other materials. In one embodiment, the conductor layer 117 can include aluminum, nickel, chromium, gold, germanium, copper, silver, titanium, tungsten, tin, platinum, and tantalum. In other embodiments, the conductor layer 117 can include other materials. In one embodiment, the conductor layer 119 can include aluminum, nickel, chromium, gold, germanium, copper, silver, titanium, tungsten, tin, platinum, and tantalum. In other embodiments, the conductor layer 119 can include other materials. In one embodiment, the dielectric layer 121 can be formed from phosphorus. In other embodiments, the dielectric layer 121 can be formed from other materials. In one embodiment, dielectric layer 123 can be formed from silicon nitride. In other embodiments, the dielectric layer 123 can be formed from other materials.

### Operation

In operation, upon exposure to light, the solar cell 100 converts light energy into electricity based on the photovoltaic effect. Some carriers reach the p-n junction and contribute to the current produced by the solar cell 100. However, other carriers recombine with no net contribution to the current produced by the solar cell 100. Solar cell efficiency is an important operational characteristic of a solar cell as solar cell efficiency is directly related to its capacity to generate power. As described herein “blistering” is a phenomena of solar cell fabrication that can significantly reduce solar cell efficiency by disrupting electrical pathways. In one embodiment, the solar cell 100 is fabricated using a process that eliminates blistering of the amorphous silicon material that is used in the passivating contacts located in the field region of the solar cell 100. In particular, the solar cell 100 includes a thin layer of carbon-containing polysilicon within those passivating contacts that helps to prevent blistering. As such, solar cell 100 is designed to avoid the significant reduction in solar cell efficiency that can be caused by blistering.

### Solar Cell Fabrication Process

FIGS. 2A-2O are illustrations of cross-sections of a multilayer semiconductor structure during fabrication of a solar cell according to one embodiment. Referring to FIG. 2A, a cross-section of a semiconductor structure 200 is shown after initial operations that include the preparation of a semiconductor wafer 201.

Referring to FIG. 2B, after one or more operations that result in the cross-section shown in FIG. 2A, a dielectric layer 203 is formed on the surface of the semiconductor wafer 201. In one embodiment, the dielectric layer 203 can include SiO₂. In other embodiments, other types of dielectric material can be used. And, in one embodiment, a semiconductor layer 205 is formed on the dielectric layer 203. In one embodiment, the semiconductor layer 205 can include a layer of intrinsic polysilicon (i-poly). In other embodiments, other types of material can be used.

Referring to FIG. 2C, after one or more operations that result in the cross-section shown in FIG. 2B, a carbon included n-type amorphous silicon layer (aSi:C) 207 is formed on the semiconductor layer 205. In addition, a dielectric layer 209 is formed on the n-type aSi:C layer 207. In one embodiment, the dielectric layer 209 can include SiNₓ. In other embodiments, the dielectric layer 209 can include other dielectric materials. In one embodiment, the n-type aSi:C layer 207 can be formed using plasma enhanced chemical vapor deposition (PECVD). In other embodiments, the n-type amorphous silicon layer 207 can be formed using other methods.

Referring to FIG. 2D, after one or more operations that result in the cross-section shown in FIG. 2C, a laser ablation of the dielectric layer 209 and the n-type aSi:C layer 207 is performed. As a part of the operation, an oxidized film 211 is formed on a part of the exposed surface of the semiconductor layer 205. In one embodiment, the oxidized film 211 can include SiO₂. In other embodiments, the oxidized film 211 can include other dielectric material. In one embodiment, two passes of a single laser pulse can be used to create the oxidized film 211. In other embodiments, other laser ablation techniques can be used.

Referring to FIG. 2E, after one or more operations that result in the cross-section shown in FIG. 2D, a semiconductor etch is performed. In one embodiment, potassium hydroxide (KOH) is used to perform the semiconductor etch. In other embodiments, other substances can be used to perform the semiconductor etch. In one embodiment, the semiconductor etch defines trenches or moats in the semiconductor layer 205. In one embodiment, the oxidized film 211 is used as a mask to protect portions of the semiconductor layer 205 that are to remain after the semiconductor etch is completed. In addition, the oxidized film 211 is used as a mask to establish the periphery of polysilicon islands 205a (see islands 107₁-107ₙ shown in FIG. 1C) that are formed in the semiconductor layer 205. In one embodiment, the semiconductor etch is performed for approximately 10 minutes using a 6% solution of KOH at 30 degrees Celsius. In other embodiments, other etching times and solutions can be used. In one embodiment, lower temperature KOH etches can be used to provide maximal SiO2 selectivity.

Referring to FIG. 2F, after one or more operations that result in the cross-section shown in FIG. 2E, a HF/O₃ clean is performed. In one embodiment the HF/O₃ clean doubles as a dielectric removal operation. In one embodiment, the HF/O₃ clean removes exposed dielectric material such as the oxidized film 211 on the surface of the polysilicon island 205a and the dielectric layer 209 formed on the surface of the n-type aSi:C layer 207.

Referring to FIG. 2G, after one or more operations resulting in the cross-section shown in FIG. 2F, a dielectric deposition is performed. In one embodiment, the dielectric deposition results in the formation of a BSG layer 213 above the Si:C layer 207 and above and around the polysilicon island 205a. In other embodiments, other types of dielectric material can be used. In addition, in one embodiment, a dielectric layer, USG layer 215, is formed above the BSG layer 213. In other embodiments, other types of dielectric material can be formed above the BSG layer 213. In one embodiment, the BSG layer 213 can be formed to have a thickness of 40 nm and the USG layer 215 can be formed to have a thickness of 75 nm. In other embodiments, the BSG layer 213 and the USG layer 215 can be formed to have other thicknesses.

Referring to FIG. 2H, after one or more operations resulting in the cross-section shown in FIG. 2G, a SiON layer 217 is formed above the USG layer 215. In one embodiment, the SiON layer 217 can be formed to have a thickness of approximately 50 nm. In other embodiments, the SiON layer 217 can be formed to have other thicknesses.

Referring to FIG. 2I, a texturing operation is performed. In one embodiment, the texturing operation causes a texturing of the frontside of the wafer 201 and some etching of the SiON layer 217. In one embodiment, the SiON layer 217 is etched slowly and is not in the texture bath sufficiently long to be completely etched (removed). In one embodiment, texturing operation can include a KOH etch with additive that can be performed at 80 degrees Celsius for 8 minutes. In other embodiments, etches having other lengths and temperatures can be performed.

Referring to FIG. 2J, after one or more operations that result in the cross-section shown in FIG. 2I, a pre-pdrive clean is performed. In one embodiment, as part of the pre-pdrive clean, a HF/O₃ bath is performed that serves to remove the SiON layer 217, slightly etch the USG layer 215 and clean the exposed textured silicon surface.

Referring to FIG. 2K, after one or more operations resulting in the cross-section shown in FIG. 2J, a pdrive operation is performed. In one embodiment, as part of the pdrive operation, a low-temperature phosphorus oxychloride (POCl) pre-deposition operation is performed to phosphorous (P)-rich oxide 219 on the textured frontside surface of the wafer 201. Thereafter, a high-temperature annealing operation is performed to drive phosphorus into the frontside surface of the wafer 201, and in the same annealing operation, boron into the polysilicon island 205a, and into the wafer and around the polysilicon island 205a, forming doped regions 216a and 216b. In addition, the high-temperature annealing operation causes the field polysilicon 205b and 205c to become n-type based on the diffusion of dopants from n-type aSi:C layer 207.

Referring to FIG. 2L, after one or more operations resulting in the cross-section shown in FIG. 2K, an HF/O₃ etch is performed. In one embodiment, the HF/O₃ etch thins the P-rich oxide 219 on the textured backside surface of the semiconductor structure 200. In addition, in one embodiment, the HF/O₃ etch causes a slight thinning of the BSG layer 213.

Referring to FIG. 2M, after one or more operations resulting in the cross-section shown in FIG. 2L, an anti-reflection coating 221 is formed on the front side and the back side of the of the semiconductor structure 200. In one embodiment, the anti-reflection coating 221 can include SiNₓ. In other embodiments, the anti-reflection coating 221 can include other materials.

Referring to FIG. 2N, after one or more operations that result in the cross-section shown in FIG. 2M, contact openings 223, 225, and 227 are formed to enable contact to be made to the p and n-type polysilicon regions.

Referring to FIG. 2O, after one or more operations that result in the cross-section shown in FIG. 2N, conductors 229, 231, and 233 are formed in contact openings 223, 225, and 227 and patterned on the backside of the semiconductor structure 200. In one embodiment, backend processes that are used to form conductors 229, 231, and 233 can include SEED (e.g., forming seed layer), Plating Mask (PLM), edge-coat, plating, and an etch back of the conductors 229, 231, and 233.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of different embodiments may be variously combined with some features included and others excluded to suit a variety of different applications.

What is claimed is:

1. A method of forming a solar cell, comprising:
forming a multilayered stack of materials including a substrate;
forming a plurality of openings in a top layer of the multilayered stack of materials;
forming a plurality of dielectric regions, that are aligned to the plurality of openings, on a polysilicon layer of the multilayered stack of materials;
forming a plurality of trenches around the plurality of dielectric regions to form a plurality of first polysilicon regions and one or more second polysilicon regions wherein the one or more second polysilicon regions include a carbon containing amorphous silicon layer on their top surface having a first doping type;
forming a dielectric layer having a second doping type above the plurality of first polysilicon regions and the carbon containing amorphous silicon layer;
in a doping operation, using the carbon containing amorphous silicon layer to cause the one or more second polysilicon regions to have the first doping type; and
in the doping operation, using the dielectric layer having the second doping type to cause the plurality of first polysilicon regions to have the second doping type.

2. The method of claim 1, wherein the carbon containing amorphous silicon layer and the one or more second polysilicon regions together form one or more first passivating contacts.

3. The method of claim 2, wherein the plurality of first polysilicon regions form a plurality of second passivating contacts.

4. The method of claim 3, wherein the one or more first passivating contacts have a thickness that is greater than a thickness of the plurality of second passivating contacts.

5. The method of claim 1, wherein the carbon containing amorphous silicon layer is a hydrogenated film.

6. The method of claim 1, wherein the forming the multilayered stack of materials includes forming a layer of amorphous silicon from which the carbon containing amorphous silicon layer is formed.

7. The method of claim 1, wherein the first doping type is n-type.

8. The method of claim 1, wherein the second doping type is p-type.

9. A solar cell, comprising:
a substrate;
a dielectric layer formed on a backside of the substrate;
at least one passivating contact having a first polarity on the dielectric layer that includes a first portion and a second portion that includes carbon containing silicon; and
a plurality of non-contiguous passivating contacts having a second polarity on the dielectric layer surrounded by the at least one passivating contact having a first polarity.

10. The solar cell of claim 9, wherein the at least one passivating contact has a thickness that is greater than a thickness of the plurality of non-contiguous passivating contacts.

11. The solar cell of claim 9, wherein the carbon containing silicon includes polycrystalline silicon.

12. The solar cell of claim 9, wherein the thickness of the first portion is greater than twice the thickness of the second portion.

13. The solar cell of claim 9, wherein the at least one passivating contact includes a hydrogenated film.

14. The solar cell of claim 9, wherein the first polarity is n-type.

15. The solar cell of claim 9, wherein the second polarity is n-type.
